(19) United States
(12) Patent Application Publication
(10) Pub. No.: US 2011/0114483 A1
(43) Pub. Date: May 19, 2011

(54) SPUTTERING DEPOSITION APPARATUS

(75) Inventor: CHUNG-PEI WANG, Tucheng (TW)

(73) Assignee: HON HAI PRECISION INDUSTRY CO., LTD., Tu-Cheng (TW)

(21) Appl. No.: 12/728,261

(22) Filed: Mar. 21, 2010

(30) Foreign Application Priority Data
Nov. 16, 2009 (CN) 200910309766.7

(51) Int. Cl. C23C 14/34

(52) U.S. Cl. 204/298.15

(57) ABSTRACT

A sputtering deposition apparatus includes a chamber device, a conveyor, a number of carriers, and a number of pairs of targets. The chamber device defines a chamber therein. The conveyor is received in the chamber and includes a smoothly extending loop rail, a conveyor belt shaped as the rail and slidably disposed on the rail, and an actuator configured to drive the conveyor belt to slide along the rail. The carriers are disposed on the conveyor belt, each of which is configured for carrying a number of substrates to be deposited with. The pairs of targets arranged along the rail, each of which are oppositely disposed outside and inside the rail.

### BACKGROUND

1. Technical Field

The present disclosure relates to film deposition apparatuses and, particularly, to a sputtering type deposition apparatus.

2. Description of Related Art

Sputtering deposition apparatuses typically include a chamber device and a holding device. The chamber device defines a vacuum chamber. The holding device is received in the vacuum chamber for holding substrates. However, current holding devices typically can hold only a small number of, typically one, substrates at a time. As such, efficiency of the sputtering deposition apparatuses is relatively low.

Therefore, it is desirable to provide a sputtering deposition apparatus, which can overcome the abovementioned limitations.

### BRIEF DESCRIPTION OF THE DRAWINGS

Many aspects of the present sputtering deposition apparatus should be better understood with reference to the following drawings. The components in the drawings are not necessarily drawn to scale, the emphasis instead being placed upon clearly illustrating the principles of the present sputtering deposition apparatus. Moreover, in the drawings, like reference numerals designate corresponding parts throughout the several views.

FIG. 1 is a cross-sectional view of a sputtering deposition apparatus, according to an exemplary embodiment.

FIG. 2 is an enlarged view of a portion II of FIG. 1.

### DETAILED DESCRIPTION

Embodiments of the present sputtering deposition apparatus will now be described in detail with reference to the drawings.

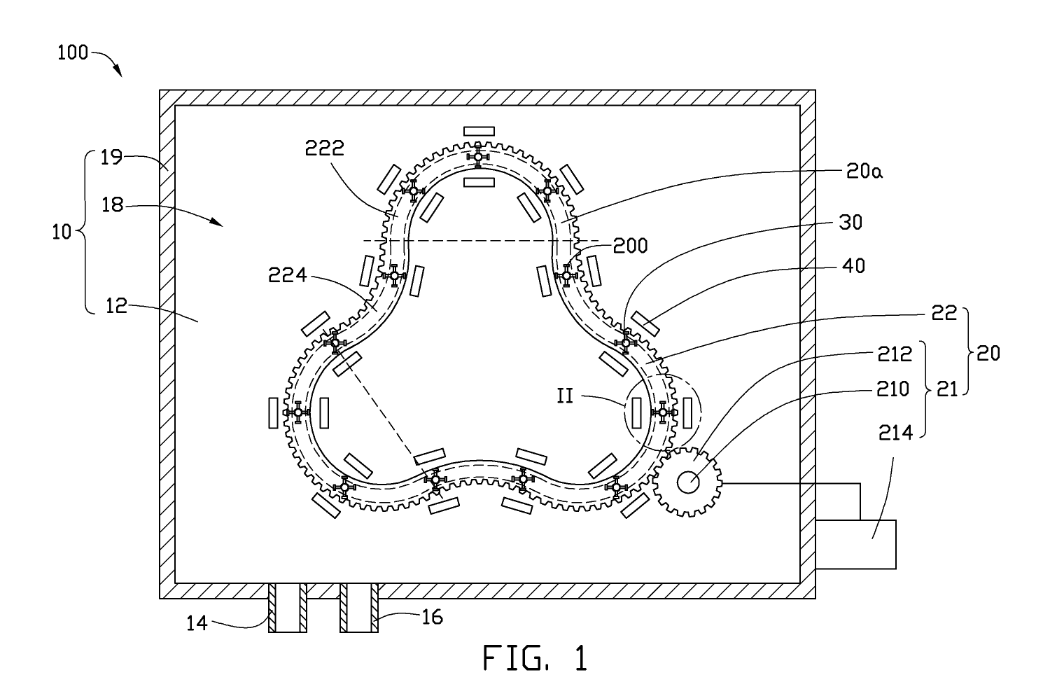

FIG. 1 is a horizontally cross-sectioned top view of a sputtering deposition apparatus 100 in accordance with an exemplary embodiment. The sputtering deposition apparatus 100 includes a chamber device 10, a conveyor 20, ten carriers 30, and ten pairs of targets 40.

The chamber device 10 is substantially a cubic shell and defines a chamber 12 therein. In particular, the chamber device 20 includes a substantially rectangular bottom board 18 and sidewalls 19 extending upward from edges of the bottom board 18. The chamber device 10 also includes an inlet tube 14 and an outlet tube 16 both embedded in one of the sidewalls 19. The inlet tube 14 connects the chamber 12 to a sputtering gas source (not shown). As such, the sputtering gas source can provide a sputtering gas, typically an inert gas such as argon, to the chamber 12 via the inlet tube 14 during sputtering deposition. The outlet tube 16 connects the chamber 12 to an air pump (not shown). As such, the air pump can vacuumize the chamber 12 prior to sputtering deposition and draw the reacted sputtering gas (see below) out of the chamber 12 via the outlet tube 16.

It is noteworthy that the chamber device 10 is not limited to this embodiment. For example, in other alternative embodiments, the chamber device can be barrel-shaped. In addition, the inlet tube and the outlet tube can be embedded in two opposite sidewalls respectively.

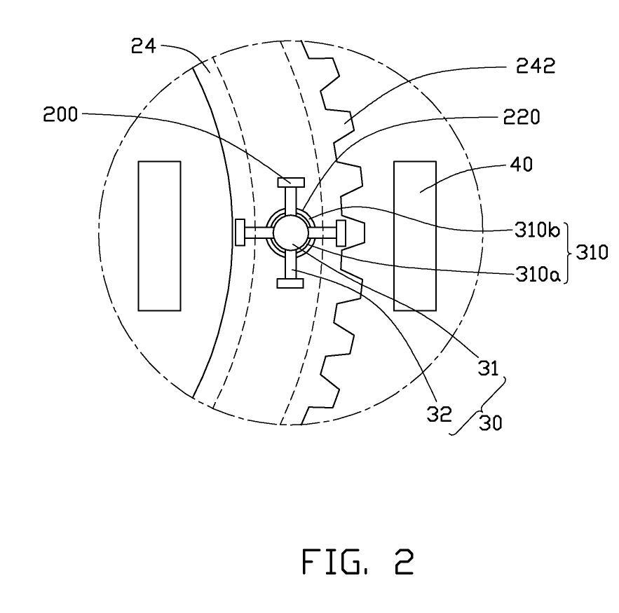

Also referring to FIG. 2, the conveyor 20 is received in the chamber 12 and disposed on the bottom board 18. In particular, the conveyor 20 includes a rail 22, a conveyor belt 24, an actuator 210, a driving gear 212, and a controller 214. The rail 22 bulges upwards from the bottom board 18 and includes three semicircular sections 222 and three connecting arc sections 224. The semicircular sections 222 and the connecting arc sections are of the same radius and are alternately arranged. The semicircular sections 222 are convex toward the sidewalls 19. The connecting arc sections 224 are convex towards the center of the bottom board 18. Each of the connecting arc sections 224 smoothly interconnects two adjacent semicircular sections 222. The conveyor belt 24 is shaped as the rail 22 and slidably disposed on the rail 22. The conveyor belt 24 defines ten equidistantly arranged positioning holes 220 and protrudes a toothed portion 242 from the outer periphery thereof. The actuator 210, such as a motor, is disposed on the bottom board 18, outside the conveyor belt 24. The driving gear 212 is coupled to the actuator 210 and meshes with the toothed portion 242. The actuator 210 is configured for driving the driving gear 212 to rotate. As such, the driving gear 212 can drive the conveyor belt 24 to slide around the rail 22. The controller 214 is configured for controlling the actuator 210 to drive the driving gear 212 to rotate.

Each carrier 30 includes a motor 310, a shaft 31, and four cantilevers 32. The motor 310 includes a stator 310a and a rotor 310b. The stator 310a is fittingly positioned in a corresponding positioning hole 220. The shaft 31 extends upward from the rotor 310b. The four cantilevers 32 extend outward from the distal end of the shaft 31 along the radial direction of the shaft 31 and are equidistantly arranged. Each cantilever 32 can hold a substrate 200.

It is noteworthy that the cantilevers 32 are not limited to this embodiment. More or fewer cantilevers 32 can be employed in other alternative embodiments and can be other than equidistantly arranged.

The pairs of targets 40 are arranged, typically equidistantly, along the rail 22. Each pair of targets are oppositely disposed at two sides (i.e., inside and outside) of the rail 22.

In operation, the substrates 200 are placed into the chamber 12 and held by the cantilevers 32. The chamber 12 is vacuumized and heated. The sputtering gas is continuously provided, ionized, and accelerated to bombard the targets 40. The targets 40 starts to sputter to deposit thin film on the substrates 200. Simultaneously, the actuator 210 continuously drives the conveyor belt 24 to convey the carriers 30 to travel along the rail 22 and the motor 310 rotates the shaft 31 so that a high degree of evenness of the thin film is archived.

It is noteworthy that the rail 22 is shaped as disclosed above to increase the length of the rail 22 within the limited size chamber 20 while the conveyor belt 24 can stably slide along the rail 22. As such, more substrates 200 can be conveyed on the conveyor belt 24. However, the rail 22 is not limited to this embodiment. More arced sections can be employed and smoothly connected to increase the length of the rail yet still smoothly convey the carriers on the conveyor belt. In fact, any smoothly extending loop rail can be used to replace the rail 22 in alternative embodiments.

It is also noteworthy that the number of the carriers 30, the pairs of targets 40, the positioning holes 220 are not limited to this embodiment but can be set depending on requirements. In addition, the stator can be directly disposed on the conveyor belt and adhered thereto. As such, the positioning holes can be omitted.

It will be understood that the above particular embodiments and methods are shown and described by way of illustration only. The principles and the features of the present disclosure may be employed in various and numerous embodiment thereof without departing from the scope of the disclosure as claimed. The above-described embodiments illustrate the scope of the disclosure but do not restrict the scope of the disclosure.

What is claimed is:

1. A sputtering deposition apparatus comprising:
a chamber device defining a chamber therein;
a conveyor received in the chamber, comprising:
a rail loop including a plurality of inwardly curved portions and a plurality of outwardly curved portions, the inwardly and outwardly curved portions alternately arranged and connected to one another;
a conveyor belt slidably disposed on the rail; and
an actuator configured to drive the conveyor belt to slide along the rail;
a plurality of carriers disposed on the conveyor belt, each carrier being configured for carrying a plurality of substrates to be deposited; and
a plurality of pairs of targets arranged along the rail loop, each pair of targets being respectively disposed at the outside and inside of the rail loop.

2. The sputtering deposition apparatus of claim 1, wherein the chamber device comprises an inlet tube, the chamber being configured for communicating with a sputtering gas source through the inlet tube.

3. The sputtering deposition apparatus of claim 1, wherein the chamber device comprises an outlet tube, the chamber being configured for communicating with an air pump through the outlet tube.

4. The sputtering deposition apparatus of claim 1, wherein the outwardly curved portions are semicircular and the inwardly curved portions are arc-shaped.

5. The sputtering deposition apparatus of claim 1, wherein the conveyor belt defines a plurality of positioning holes therein, the carriers being positioned and held in the positioning holes respectively.

6. The sputtering deposition apparatus of claim 1, wherein the carriers are adhered to the conveyor belt.

7. The sputtering deposition apparatus of claim 1, wherein the conveyor belt comprises a toothed portion protruding outward, the conveyor comprising a driving gear coupled to the actuator and meshed with the toothed portion.

8. The sputtering deposition apparatus of claim 1, wherein the actuator comprises a motor.

9. The sputtering deposition apparatus of claim 1, wherein each carrier is configured for rotating the substrates held thereto around a central axis thereof.

10. The sputtering deposition apparatus of claim 1, where each carrier comprises a motor disposed on the conveyor belt, a shaft coupled to the motor, and a plurality of cantilevers radially extending outward from the shaft, the motor being configured to drive the shaft to spin, each of the cantilevers being configured to hold a substrate.
